(19) United States
(12) Patent Application Publication
(10) Pub. No.: US 2006/0045966 A1
(43) Pub. Date: Mar. 2, 2006

(54) Method of forming colored layers of color image display unit

(75) Inventors: Satoshi Suzuki, Kyoto-shi (JP); Kazuo Kinose, Kyoto-shi (JP)

Correspondence Address: MCDERMOTT WILL & EMERY LLP, 600 13TH STREET, N.W., WASHINGTON, DC, 20005-3096, US

(73) Assignee: DAINIPPON SCREEN MFG. CO., LTD.

(21) Appl. No.: 11/200,189

(22) Filed: Aug. 10, 2005

(30) Foreign Application Priority Data
Aug. 24, 2004 (JP) 2004-244010

(51) Int. Cl. B05D 5/06

(52) U.S. Cl. 427/164; 427/58

(57) ABSTRACT

A method is capable of easily forming a colored layer such as color filters or organic EL layers only in an active region on a transparent substrate for manufacturing a color liquid crystal display or an organic EL display unit. The method includes the steps of: forming a fine partition of a predetermined pattern using a light-blocking material in an active region on the surface of the transparent substrate, and depositing a light-blocking material into a non-active region; applying plural colors of coloring materials containing a colorant and a photosensitive resin into fine recesses separated by the fine partitions while relatively scanning a nozzle discharging a coloring material with respect to the transparent substrate; exposing the transparent substrate from back side to apply the plural colors and cure; and developing the surface side of the transparent substrate, dissolving the coloring materials applied into the non-active region and remaining not cured, and removing the materials.

### BACKGROUND OF THE INVENTION

1. Field of the Invention

The present invention relates to a method of forming colored layers on a transparent substrate in color image display units such as flat panel displays (FPD), e.g., color liquid crystal displays, or organic EL (electro luminescence) display units, in which transmitted lights are colored by a color filter or colored lights are transmitted by the organic EL layer itself by application of voltage.

2. Description of the Related Art

For example, a color filter of a color liquid crystal display has been conventionally manufactured by using color resists of three colors, red, green and blue having photosensitivity, and repeating three times each process of resist application onto a glass substrate→pre-bake→exposure→development. However, in accordance with this method, the process is complicated, a series of unit process needs to be repeated as many as three times, and yield is low. These facts result in one of factors of high production cost of a liquid crystal display. To overcome this, several attempts of directly applying coloring materials onto a glass substrate in a predetermined pattern have been proposed recently, using ink-jet printing or continuous discharge printing under the background of increasingly upgraded printing technique.

On the other hand, an organic EL layer of an organic EL display unit is formed on a glass substrate as follows by printing method (continuous discharging method). That is, plural stripes of electrodes are formed in a predetermined pattern on the surface of the glass substrate using a transparent electrode material, for example ITO (indium tin oxide); partitions having electrical insulating properties that protrude from the glass substrate are formed so as to surround each of those stripe-shaped electrodes using an electrical insulating material, for example, chrome (Cr) or dry film; thereafter while linearly moving a nozzle head equipped with three nozzles that discharge organic EL materials of three colors, red, green and blue, along stripe-shaped grooves formed by the partitions, each color of organic EL materials are discharged into each of the grooves adjacent to each other from each of the nozzles, thus the organic EL materials being run and applied into the grooves; and these operations are repeated while the glass substrate is fed in a direction perpendicular to a moving direction of the nozzles with a pitch of three lines of grooves; whereby an organic EL layer of stripe array, in which the organic EL materials of three colors, red, green and blue are applied in a number of grooves, will be formed (for example, see the Japanese Patent Publication (unexamined) No. 75640/2002 (Page 5, FIGS. 2, 3, 6 and 7)).

However, in the foregoing method of forming on a glass substrate a color filter of a color liquid crystal display or an organic EL layer of an organic EL display unit by printing methods such as ink-jet printing or continuous discharge printing, particularly in the continuous discharge printing, as shown in FIG. 8 being a plan view, a problem exists in that coloring materials 4 are also applied to a non-active region 3 on the surface of the substrate 1 other than active regions 2 corresponding to image display surfaces on which picture elements are formed. It is possible to solve these problems by controlling with accuracy positions of starting and ending the discharge of coloring materials from the nozzles, and causing the nozzles to move at lower speed. In this case, however, a further problem exists in that such control is extremely hard to be made, and throughput is decreased, as well as it comes to be difficult to obtain colored layers having a required film thickness, which is impractical after all.

### SUMMARY OF THE INVENTION

The present invention was made in view of the state of arts described above, and has an object of providing a method of forming colored layers of a color image display unit by which colored layers such as color filters or organic EL layers can be easily formed only in an active region on a transparent substrate, in the case of manufacturing color image display units such as flat panel displays including color liquid crystal displays or organic EL display units.

An invention according to claim 1 relates to a method of forming a colored layer of a color image display unit in which plural colors of coloring materials are deposited on a transparent substrate in a predetermined pattern to form a colored layer, the method comprising the steps of:

forming a fine partition of a predetermined pattern configuration using a light-blocking material in an active region corresponding to an image screen on the surface of the transparent substrate, and causing a light-blocking material to be deposited in a non-active region other than the mentioned active region on the surface of the transparent substrate;

applying plural colors of coloring materials each of which contains a colorant and a photosensitive resin into fine recesses separated by the mentioned fine partitions while relatively scanning a nozzle that discharges a coloring material to the mentioned transparent substrate so that the coloring materials are not mixed with each other;

exposing the mentioned transparent substrate from back side to cure plural colors of coloring materials having been applied into the mentioned fine recesses respectively; and

developing the surface side of the mentioned transparent substrate, dissolving the coloring materials having been applied into the mentioned non-active region and remaining not cured, and removing the coloring materials.

According to the method of forming a colored layer of a color image display unit of the invention as defined in claim 1, when coloring materials that contain a colorant and a photosensitive resin are applied onto the transparent substrate and thereafter the transparent substrate is exposed from back side, the coloring materials having been applied into the fine recesses in the active region on the transparent substrate are exposed through the transparent substrate and photo-cured; while the coloring materials having been applied into the non-active region on the transparent substrate is shielded from light with light-blocking material having been deposited in the non-active region and is not exposed, so that it will not be cured. Therefore, when the surface side of the transparent substrate is developed, only the coloring materials having been applied into the non-active region and remaining not cured are dissolved and removed. As a result, according to the method of the invention, in the case of manufacturing a color image display unit such as flat panel displays, e.g., color liquid crystal displays or organic EL display units, it is possible to easily form a colored layer such as color filters or organic EL layers only in the active region on the transparent substrate.

The invention according to claim 2 is dependent on the method according to claim 1, and is characterized in that the mentioned colored layer is a color filter of a color liquid crystal display.

According to the method of the invention as defined in claim 2, a color filter of the color liquid crystal display is easily formed only in the active region on the transparent surface.

The invention according to claim 3 is dependent on the method according to claim 1 or 2, and is characterized in that the mentioned coloring material is applied by continuous discharge printing.

According to the method of the invention as defined in claim 3, a colored layer such as color filters of a color liquid crystal display or organic EL layers of an organic EL display unit is easily formed only in the active region on the transparent substrate by continuous discharge printing.

The invention according to 4 is dependent on the method according to claim 1 or 2, and is characterized in that the mentioned coloring material is applied by ink-jet printing.

According to the method of the invention as defined in claim 4, a colored layer such as color filters of a color liquid crystal display or organic EL layers of an organic EL display unit is easily formed only in the active region on the transparent substrate by ink-jet printing.

### BRIEF DESCRIPTION OF THE DRAWINGS

FIG. 1 shows an example of preferred embodiments according to the present invention, is a view for explaining each step in the method of forming colored layers of a color image display unit, and is a perspective view of a glass substrate on which fine partitions of a predetermined pattern are formed.

FIG. 2A is a partially enlarged cross sectional view of A portion of FIG. 1 taken in a direction indicated by the arrow a, and FIG. 2B is a partially enlarged cross sectional view of B portion of FIG. 1 taken in a direction indicated by the arrow b.

FIG. 3 is a partially enlarged plan view showing a state in which coloring materials are applied onto the surface of the glass substrate by continuous discharge printing.

FIGS. 4A and 4B show a state in which coloring materials are applied onto the surface of the glass substrate; and in which FIG. 4A is a partially enlarged cross sectional view of A portion of FIG. 1 taken in a direction indicated by the arrow a, and FIG. 4B is a partially enlarged cross sectional view of B portion of FIG. 1 taken in a direction indicated by the arrow b.

FIGS. 5A and 5B show a state that the glass substrate is exposed to light from the back side; and in which FIG. 5A is a partially enlarged cross sectional view of A portion of FIG. 1 taken in a direction indicated by the arrow a, and FIG. 5B is a partially enlarged cross sectional view of B portion of FIG. 1 taken in a direction indicated by the arrow b.

FIGS. 6A and 6B show a state that the surface side of the glass substrate is developed; and in which FIG. 6A is a partially enlarged cross sectional view of A portion of FIG. 1 taken in a direction indicated by the arrow a, and FIG. 6B is a partially enlarged cross sectional view of B portion of FIG. 1 taken in a direction indicated by the arrow b.

FIG. 7 shows another embodiment according to the invention, and is a partially enlarged plan view for explaining an example of forming a color filter on the glass substrate by ink-jet printing.

FIG. 8 is a schematic plan view for explaining the problems incidental to the prior art in the case of forming colored layers of a color image display unit by continuous discharge printing.

### BEST MODE FOR CARRYING OUT THE INVENTION

Hereinafter, a best mode for carrying out the present invention is described referring to the drawings.

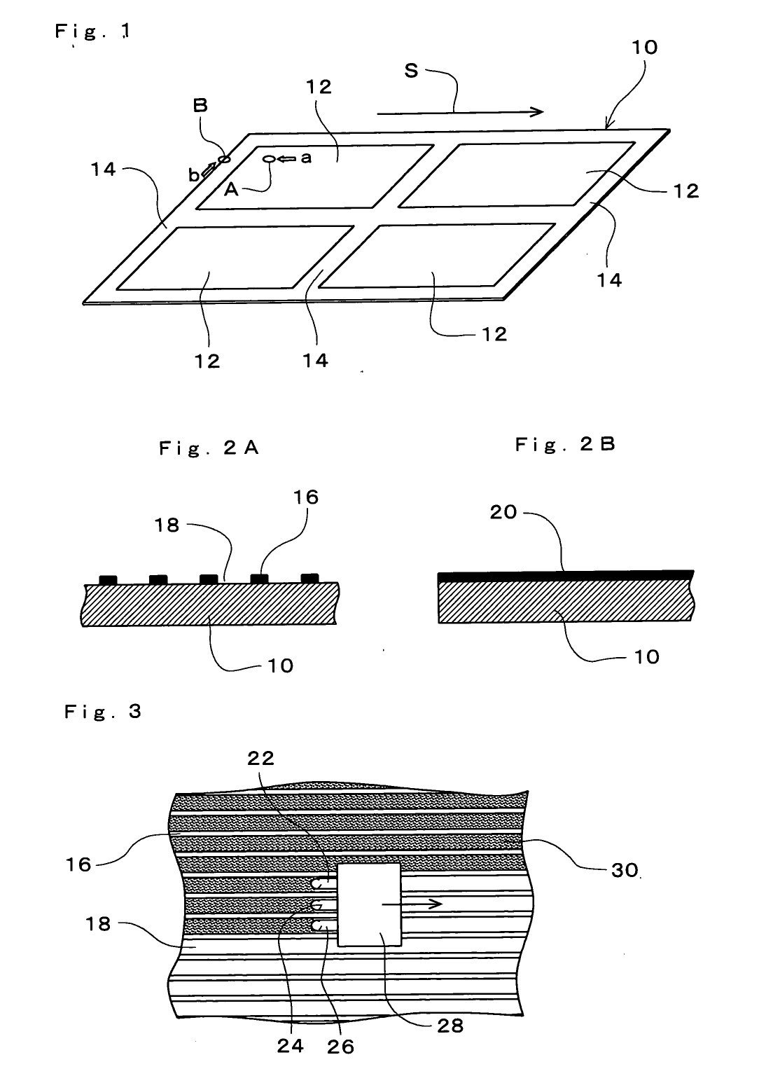

FIGS. 1 to 6 show an embodiment according to the invention, and are views for explaining each step in the method of forming colored layers of a color image display unit. This embodiment shows an example of forming color filters of a color liquid crystal display on a glass substrate by continuous discharge printing.

FIGS. 1 and 2 show a state that fine partitions of a predetermined pattern are formed on a transparent glass substrate. FIG. 1 is a perspective view. FIG. 2A is a partially enlarged cross sectional view of A portion of FIG. 1 taken in a direction indicated by the arrow a, and FIG. 2B is a partially enlarged cross sectional view of B portion of FIG. 1 taken in a direction indicated by the arrow b. In this embodiment, there are provided four active regions 12 corresponding to image display surfaces on which picture elements are formed.

In the active region 12, as shown in FIG. 2A, a number of fine light-shielding partitions 16 are formed in a predetermined pattern with the use of material having light blocking effect, and elongated grooves 18 are formed in a stripe shape between the adjacent light-shielding partitions 16. On the other hand, in a non-active region 14 other than the active region 12, light-blocking material is applied all over, and a light-shielding layer 20 will be deposited and formed. A photosensitive resin material in combination with, for example, black pigments or carbon blacks is used as a light-blocking material. The striped light-shielding partitions 16 are formed on the surface of the glass substrate 10, for example, by photolithography or printing technique.

Next, coloring materials (ink) of plural colors, for example, three colors, red, green and blue are applied onto the surface of a glass substrate by continuous discharge printing. Although detailed description of the construction of a continuous discharge-type coating applicator is omitted, the following coating applicator is employed. That is, as shown in FIG. 3, being a partially enlarged plan view, this coating applicator is equipped with a nozzle head 28 including three nozzles 22, 24, 26 that discharge coloring materials of three colors, red, green and blue, and possesses such a mechanism as to be capable of continuously discharging the coloring materials from each of the nozzles 22, 24, 26 respectively while linearly moving the foregoing nozzle head 28 in a direction along the elongated grooves 18, which are formed on the glass substrate 10, (in a scanning direction S indicated by an arrow in FIG. 1), and to be capable of feeding a stage (not shown) onto which the glass substrate 10 is mounted and fixed, or the nozzle head 28 with a pitch of three lines of elongated grooves 18 in a direction perpendicular to the scanning direction. The three nozzles 22, 24, 26 that are mounted on the nozzle head 28 are disposed at intervals of the same distance as that between the adjacent elongated grooves 18. A coloring material contains each color of colorants such as organic pigments, inorganic pigments, or dyes, and a photosensitive resin of negative type. Further, to prevent color mixing, it is preferable to be constructed such that a single nozzle is mounted on one nozzle head, and there are provided individual nozzle heads with respect to each color of red, green and blue, and to apply each color of coloring materials by feeding each of the nozzle heads in a direction perpendicular to the scanning direction with a pitch of three lines of elongated grooves 18. Furthermore, it is preferable to be constructed such that there are provided individual nozzle heads each of which includes a plurality of nozzles, for example, three nozzles that are located at an interval corresponding to two lines of elongated grooves 18 with respect to each color of red, green and blue, and to apply each color of coloring materials by feeding each of the nozzle heads in a direction perpendicular to the scanning direction with a pitch of nine lines of elongated grooves 18.

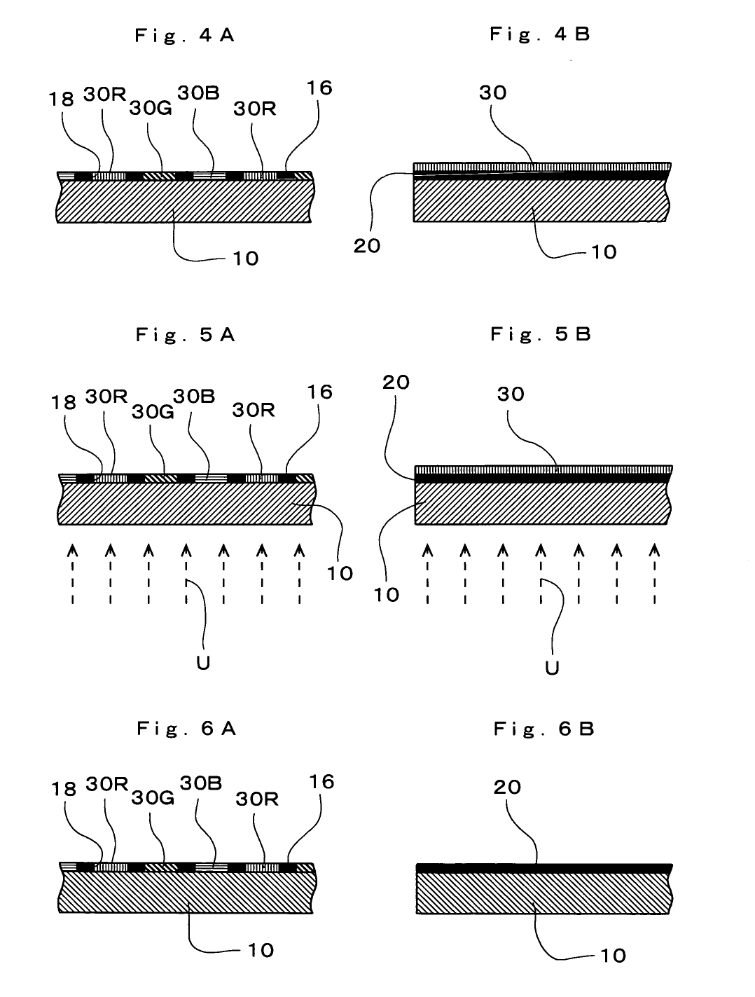

Using the continuous discharge-type coating applicator as described above, as shown in FIG. 3, while linearly moving the nozzle head 28 along the elongated grooves 18, each color of coloring materials 30 are discharged from each of the nozzles 22, 24, 26 into each of the elongated grooves 18 adjacent to each other so that the coloring materials are not mutually mixed, and the coloring materials 30 are run and applied into the elongated grooves 18. These operations are repeated while feeding the glass substrate 10 in a direction perpendicular to a scanning direction of the nozzles 22, 24, 26 relatively with a pitch of three lines of the elongated grooves 18. In this manner, a number of coloring materials of the three colors, red, green and blue will be applied in sequence. FIG. 4A is a partially enlarged cross sectional view of A portion of FIG. 1 taken in a direction indicated by the arrow a. As shown in this FIG. 4A, a colored layer of stripe array in which a red coloring material 30R, a green coloring material 30G, and a blue coloring material 30B are applied in sequence into each of the elongated grooves 18 that are formed by the light-shielding partitions 16 on the surface of the glass substrate 10. On the other hand, FIG. 4B is a partially enlarged cross sectional view of B portion of FIG. 1 taken in a direction indicated by the arrow b. As shown in this FIG. 4B, however, the coloring materials 30 are applied in a striped pattern onto the surface of the light-shielding layer 20 also in the non-active region 14 of the glass substrate 10.

When the application process of coloring materials has completed, as shown in FIG. 5A, the back side of the glass substrate 10 is irradiated with light U such as ultraviolet rays, and the coloring materials 30R, 30G, 30B having been applied into the elongated grooves 18 are exposed through the glass substrate 10. Whereby, the coloring materials 30R, 30G, 30B are photo-cured due to the fact that these coloring materials contain a negative-type photosensitive resin. On the other hand, as shown in FIG. 5B, it is certain that the non-active region 14 of the glass substrate 10 is irradiated with the light U as well, but since the light-shielding layer 20 is deposited on the glass substrate 10 in the non-active region 14, the light is blocked by the light-shielding layer 20, and the coloring material 30 in the non-active region 14 is not exposed, and not cured.

Subsequently, when the surface side of the glass substrate 10 is developed after having been exposed, as shown in FIG. 6A, the coloring materials 30R, 30G, 30B are not changed at all in the active region 12 of the glass substrate 10 due to the fact that they are cured. On the other hand, as shown in FIG. 6B, the coloring materials 30 that are not cured are dissolved and removed in the non-active region 14 of the glass substrate 10. Through the process as described above, a striped color filter in which the coloring materials 30R, 30G, 30B are applied only into the active region 12 of the glass substrate 10 is formed.

Further, according to the foregoing first embodiment, coloring materials are applied onto the glass substrate 10 provided with four active regions 12. However, also with respect to a glass substrate that includes a single active region and there is provided a non-active region around this active region, the method according to the invention is likewise applicable, and the same function and advantage as described above can be obtained.

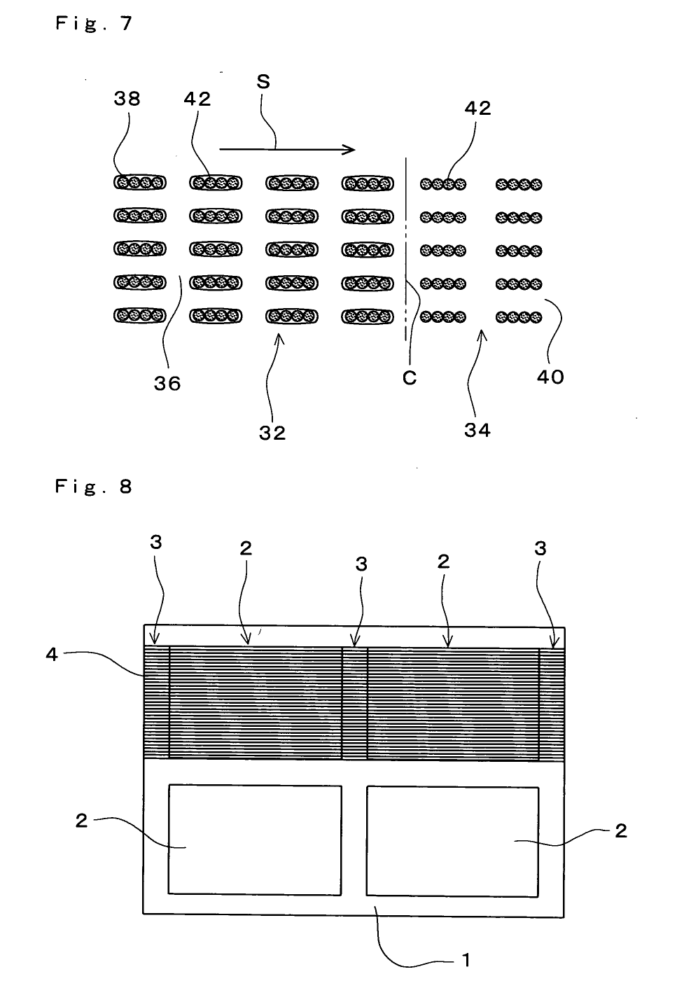

Furthermore, according to the above-mentioned embodiment, the method of forming a color filter of a color liquid crystal display on a glass substrate performed by continuous discharge printing is described. However, in the case of forming a color filter on a glass substrate by ink-jet printing, the invention is preferably applicable. That is, as shown in FIG. 7, being a partially enlarged plan view of a glass substrate, light-shielding partitions 36 are formed using a light-blocking material on a glass substrate in an active region 32 zoned at a position of a two-dot chain line C (referred to as “black matrix”) to form a number of fine recesses 38 separated by the light-shielding partitions 36; as well as a light-shielding layer 40 is deposited and formed using a light-blocking material on the glass substrate in a non-active region 34 other than the active region 32. Thereafter, even if a coloring material 42 is discharged and adhered to the non-active region 34 when the coloring material 42 (ink) is discharged into the fine recesses 38 while scanning the nozzles in a direction indicated by an arrow S with the use of an ink-jet type coating applicator to form a colored layer, the coloring material 42 having adhered to the non-active region 34 can be easily removed by carrying out the method according to the invention to undergo the exposure and development steps.

In addition, the invention is applicable also in the case of forming organic EL layers of an organic EL display unit other than the case of manufacturing color filters of a color liquid crystal display unit. In this case, an material obtained by application of a photosensitive resin to an organic EL material is used as a coloring material.

It is to be understood that the disclosures are for the purpose of illustration and that various changes and modifications may be made without departing from the scope of the invention as set forth in the appended claims.

What is claimed is:

1. A method of forming a colored layer of a color image display unit in which plural colors of coloring materials are deposited on a transparent substrate in a predetermined pattern to form a colored layer, the method comprising the steps of:
forming a fine partition of a predetermined pattern configuration using a light-blocking material in an active region corresponding to an image screen on the surface of the transparent substrate, and causing a light-blocking material to be deposited in a non-active region other than said active region on the surface of the transparent substrate;
applying plural colors of coloring materials each of which contains a colorant and a photosensitive resin into fine recesses separated by said fine partitions while relatively scanning a nozzle that discharges a coloring material to said transparent substrate so that the coloring materials are not mixed with each other;
exposing said transparent substrate from back side to cure plural colors of coloring materials having been applied into said fine recesses respectively; and
developing the surface side of said transparent substrate, dissolving the coloring materials having been applied into said non-active region and remaining not cured, and removing the coloring materials.

2. The method of forming a colored layer of a color image display unit according to claim 1, wherein said colored layer is a color filter of a color liquid crystal display.

3. The method of forming a colored layer of a color image display unit according to claim 1 or 2, wherein said coloring material is applied by continuous discharge printing.

4. The method of forming a colored layer of a color image display unit according to claim 1 or 2, wherein said coloring material is applied by ink-jet printing.
